(19) United States
(12) Patent Application Publication
(10) Pub. No.: US 2007/0020807 A1
(43) Pub. Date: Jan. 25, 2007

(54) Protective structures and methods of fabricating protective structures over wafers

(76) Inventors: Frank S. Geefay, Cupertino, CA (US); Richard C. Ruby, Menlo Park, CA (US)

Correspondence Address: AVAGO TECHNOLOGIES, LTD., P.O. BOX 1920, DENVER, CO, 80201-1920, US

(21) Appl. No.: 11/540,412

(22) Filed: Sep. 28, 2006

Related U.S. Application Data
(63) Continuation-in-part of application No. 10/985,312, filed on Nov. 9, 2004.

(51) Int. Cl. H01L 21/00

(52) U.S. Cl. 438/106

(57) ABSTRACT

A method of fabricating a protective structure and a packaged structure are described.

### CROSS-REFERENCE TO RELATED APPLICATIONS

The present application is a continuation-in-part of U.S. patent application Ser. No. 10/985,312 (Publication Number 20060099733), entitled “Semiconductor Package and Fabrication Method” to Frank S. Geefay, et al., and filed on Nov. 9, 2004. Priority from the referenced application is claimed under 35 U.S.C. §120. The disclosure of the referenced application is specifically incorporated herein by reference.

### BACKGROUND

Wafer-level processing continues to evolve as new applications are both desired and realized. In certain instances, it is useful to provide a protective structure or other packaging structure over a portion of the wafer. This structure may be disposed over components formed from or otherwise disposed over the wafer. Often, a void or air gap is provided between the structure and the wafer.

One known method for forming structures over a wafer includes forming a dissolvable material over the wafer. Next, a layer of material is disposed over the dissolvable material. After the material is processed, the dissolvable material is dissolved using a solute and removed. Thus, a void is provided between the structure formed of the material.

While the noted method provides a useful structure, there are certain disadvantages and shortcomings. Notably, the method requires the dissolvable material to be disposed on components that are often delicate. For example, components such as micro-electro-mechanical (MEM) components are often too delicate to withstand not only the formation of the dissolvable material thereover, but also its removal by the solute. Moreover, the noted process is rather complex and labor intensive. These traits often raise fabrication costs. Accordingly, the method noted above is not attractive for at least this reason as well.

What is needed, therefore, is a fabrication method that overcomes at least the shortcomings described above.

### SUMMARY

In accordance with an illustrative embodiment a method of forming a protective structure includes disposing a layer of material over a first substrate. The method also includes defining features of the protective structure in the layer of material and bonding the protective structure to a second substrate. The method also includes separating the first substrate from the second substrate.

In accordance with another illustrative embodiment, a packaged structure includes a protective structure, which includes a cap and a gasket comprised of a photo-definable material.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A-1I are cross-sectional views illustrating a method of fabricating a protective structure in accordance with a representative embodiment.

FIG. 2 is a cross-sectional view of a packaged component in accordance with a representative embodiment.

FIGS. 3A-3M are cross-sectional views illustrating a method of fabricating a protective structure in accordance with a representative embodiment.

FIG. 4 is a cross-sectional view of a packaged component in accordance with a representative embodiment.

### DEFINED TERMINOLOGY

The terms ‘a’ or ‘an’, as used herein are defined as one or more than one.

The term ‘plurality’ as used herein is defined as two or more than two.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of apparatuses, materials and methods known to one of ordinary skill in the art may be omitted so as to not obscure the description of the example embodiments. Such apparati, methods and materials are clearly within the scope of the present teachings.

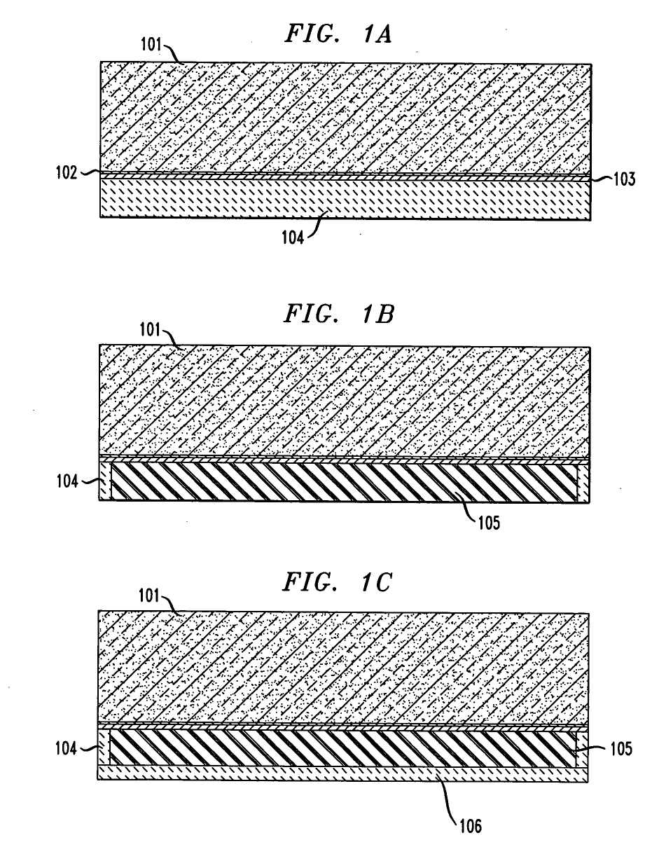

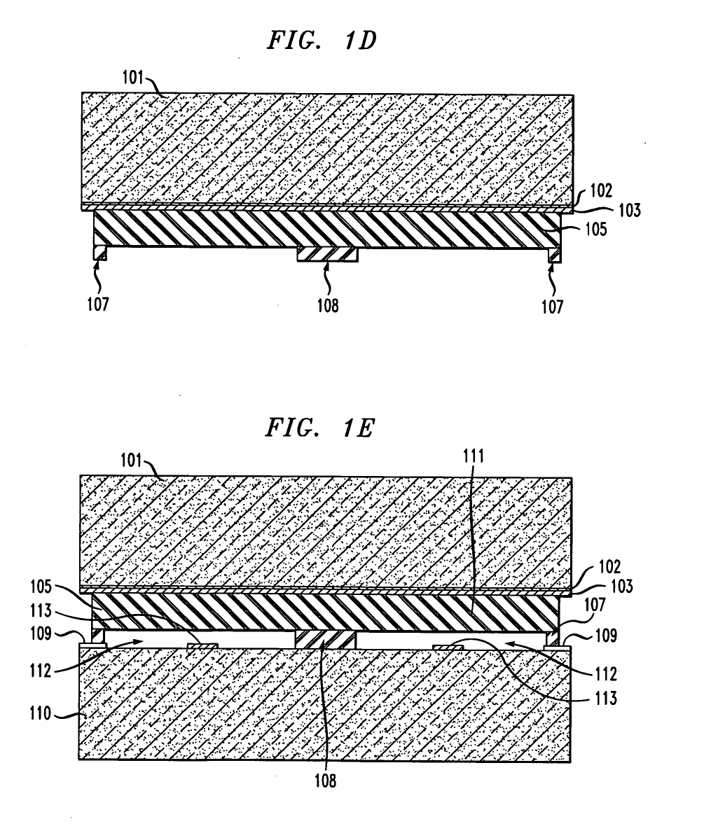

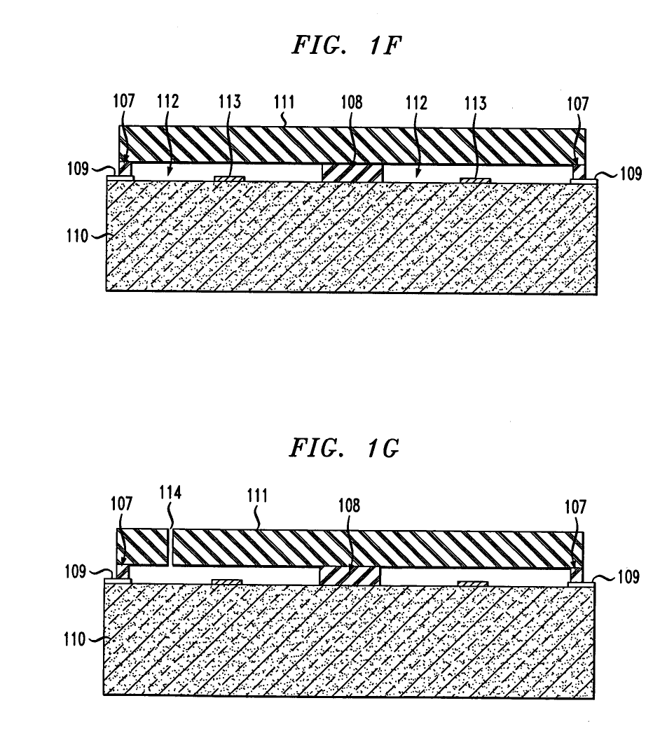

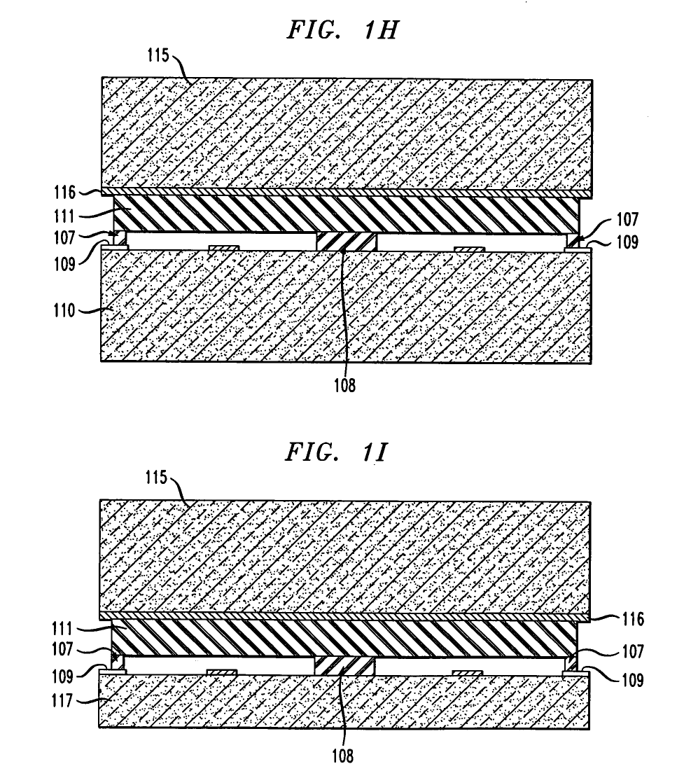

FIGS. 1A-1I are cross-sectional views showing a process sequence of a method in accordance with a representative embodiment. The method may be implemented in a variety of packaging applications, such as MEM systems and other wafer-scale processing applications. It is emphasized that these are merely illustrative applications and that other applications within the purview of one of ordinary skill in the art are contemplated.

FIG. 1A shows a first substrate 101 having an optional first layer 102 disposed thereover. As described herein, the first layer 102 is an adhesive layer. A second layer 103 is disposed over the first layer 102. A layer 104 of material is disposed over the second layer 103. As will become clearer as the present description continues, the layer 104 is processed to form a protective structure or a portion of a protective structure.

The first substrate 101 is a transfer substrate used in the fabrication of the protective structure, and may be referred to herein as such. In embodiments, the first substrate 101 may be used repeatedly, if desired, thereby allowing a large number of protective structures to be formed over a large number of wafers.

In representative embodiments, the first substrate 101 may be one or more of a number of materials. Beneficially, the first substrate 101 comprises a comparatively strong material(s) that has a thermal coefficient of expansion similar to that of device substrate over which it is disposed. As will become clearer as the present description continues, the first substrate 101 usefully is also able to withstand various chemicals and processes undertaken in the fabrication of the protective structure; and subsequent processing if applicable. In addition, the first substrate 101 must be hard enough to withstand scratching and other abrasions so that it can be reused multiple times. For purposes of illustration, if the device substrate is GaAs or some other III-V semiconductor, then ceramic (e.g., Alumina) substrates could be employed as the first (transfer) substrate 101. Alternatively, the first substrate 101 may be single-crystal silicon, crystalline quartz, fused silica, or sapphire. Other materials within the purview of one of ordinary skill in the art are also contemplated.

In the present representative embodiment, the first and second layers 102, 103 are metals. The first layer 102 may be titanium (Ti), nickel-chromium or other material suitable for adhering to the first substrate 101. The second layer 103 is illustratively gold (Au) or other Noble Metal that is selected to adhere to the layer 104 by comparatively weak electrostatic forces (e.g., Van der Waals forces). As described more fully herein, the use of such materials as the second layer 103 allows the separation of the first substrate 101 from the device substrate without excessive force.

In representative embodiments, the layer 104 is a photo-definable material, such as a photo-definable polymer. By using a photo-definable material, the fabrication of features in the protective structure may be simplified by eliminating at least one photoresist patterning step and at least one etching step. Illustratively, the layer 104 may be benzocyclobutene (BCB), polyimide or a photoimagable epoxy that comprises an epoxyfunctional resin adapted for curing by an action of a cation-producing photoinitiator. In certain embodiments, the photoimagable epoxy is a negative photoresist commercially available from MicroChem Corporation of Newton, Mass. USA and sold under the tradename SU-8 and progeny thereof. This photoresist is also described in U.S. Pat. No. 4,882,245, the disclosure of which is specifically incorporated herein by reference. It is emphasized that the noted materials are in no way an exhaustive list and that other materials are contemplated. Such materials will become apparent to one of ordinary skill in the art after reviewing the present disclosure.

The layer 104 is disposed over the second adhesive layer 103 using a known spin-on method. The thickness of the layer 104 is normally greater than approximately 10.0 μm and may be as thick as approximately 100.0 μm. The thickness is often a function of the selected material. For example, BCB is normally difficult to spin-on in thicknesses greater than approximately 15.0 μm; polyimide may be spun on to a thickness of approximately 30.0 μm; and SU-8 may be spun-on to a thickness of approximately 100.0 μm.

It is noted more than one type of material may be used for layer 104. For example, certain features of the protective structure formed from the layer 104 may require additional mechanical strength and certain materials that provide this characteristic may be used as a first material. Other features may require certain adhesive properties and materials that provide this characteristic may be used as a second material of the layer 104.

In addition to photo-definable polymers, the layer 104 may be a non-photo definable polymer such as a liquid crystal polymer (LCP) could also be used but additional process steps not shown or described herein may be needed to define the features of the protective structure.

FIG. 1B shows a cap layer 105 having been formed by the exposure under mask of the layer 104. In the present illustrative embodiment, the layer 104 is a photo-definable layer having been exposed to light of a suitable wavelength through a mask (not shown). After exposure, the photo-definable material is developed with a developing chemical to form the photolithographic pattern of the cap layer 105. Thereafter the cap layer 105 is cured in a soft-bake sequence known to those skilled in the art to provide the cap layer 105. However, as is described more fully herein, the developing and curing of the cap layer 105 may be effected after subsequent process steps.

In other embodiments incorporating non-photodefinable material for layer 104, a photoresist is patterned over the layer 104 and the layer 104 is etched by known methods.

FIGS. 1C-1D show the sequence of formation of a gasket 107 and an optional bridge 108. The gasket 107 and bridge 108 may be formed from another layer 106 of material, which is similar or identical to that of layer 104, and is deposited to a suitable thickness. Alternatively, the layer 106 may be of another material chosen for a desired property, such as adhesion to the device substrate.

The gasket 107 and the bridge 108 may be formed by exposing the layer 106 under mask. In one representative embodiment, the gasket 107 and bridge 108 may be developed after the cap layer 105 is developed. Alternatively, the gasket 107 and bridge 108 may be developed concurrently with the cap layer 105. In either case, the gasket 107 defines cavities in a grid-like manner over the device substrate. The bridge 108 may further define cavities. As will become clearer as the present description continues, the cap 105, gasket 107 and optional bridge 108 usefully provide a semi-hermetic mechanical protective structure over devices and components.

FIG. 1D shows the cap layer 105, the gasket 107 and the bridge 108 formed over the substrate 101 after developing. As noted, the cap layer 105 may be cured prior to this step in the method. However, this is not essential and may not be fortuitous depending on the adhesive material selected for layer 103. For example, if gold is selected for the second layer 103, curing the cap layer 105 may result in the adhesion of the gold to the cap layer 105, which may not be desirable. Moreover, in the present representative embodiment, the gasket 107 and bridge 108 are not cured at this point in the method. To this end, once cured, depending on the material chosen for the gasket 107 and bridge 108, it may be difficult to properly adhere the protective structure to the device substrate. Accordingly, in a representative embodiment, the gasket 107 and bridge 108 are cured at a later point in the method.

The gasket 107 usefully has a width (horizontal dimension of FIG. 1D) that is greater than approximately 20.0 μm and a height (thickness in the vertical direction of FIG. 1D) in the range of approximately 5.0 μm to approximately 30.0 μm. The gasket 107 can extend considerably into the area of the cap layer 105 as appropriate and can have many shapes. Notably, the outer perimeter of the gasket 107 should follow the contour of the cap layer 105 closely.

In alternative embodiments, the gasket 107 and bridge 108 may be cured before the protective structure is adhered to the device substrate. However, in order to ensure proper adhesion of the protective structure to the device substrate, another layer may be provided over the gasket 107 the bridge 108. This may be another layer of photodefinable material (not shown in FIG. 1D) formed by exposing and developing as described above. Alternatively, other suitable adhesive materials within the purview of one of ordinary skill in the art may be used.

FIG. 1E shows the first substrate 101 disposed over a second substrate 110 (the device substrate) with a protective, which comprises the cap 105, gasket 107 and bridge 108, disposed between the first and second substrates 101, 110.

The second substrate 110 may be one of a variety of substrate materials used for IC, very large scale integrated (VLSI) circuit and ultra-large scale integrated (ULSI) circuit applications. Representative materials include, but are not limited to silicon, silicon-germanium (SiGe), III-V semiconductors as well as substrates commonly used in high frequency applications such as ceramic materials. It is emphasized that this list is not exhaustive, and that other materials are contemplated for the second substrate 110.

A layer 109 of adhesive material is optionally provided between the gasket 107 and the second substrate 110. This layer 109 may be used to promote adhesion between the second substrate 110 and the protective structure 111. As will be appreciated by one of ordinary skill in the art, the need and material chosen for the layer 109 depends on the materials chosen for the gasket 107 and second substrate 110. For example, if BCB were selected for the gasket 107, titanium or silicon nitride may be used for the layer 109, because BCB exhibits poor adhesion to many materials (e.g., GaAs) that are often selected for the second substrate 110.

After placement of the protective structure 111, adhesion of the protective structure 111 to the second substrate 110 is carried out. In one embodiment, heating or baking to a temperature near the glass transition temperature is used to soften the polymer material of the gasket 107 and bridge 108 to ensure good adhesion of the protective structure 111 to the second substrate 110. Moreover, the cap 111 is pressed onto the substrate 110 with a comparatively significant force to aid in the bonding. This may be carried out using a known wafer bonding machine.

The heating step may also be used to cure any uncured polymer material. For example, if the gasket 107 and bridge 108 were uncured prior to adhesion to the second substrate 110, in order to ensure proper adhesion of the polymer to the second substrate, the heating sequence to adhere the structure 111 to the second substrate 110 usefully cures the polymer as well.

Cavities 112 are provided between the second substrate 110 and the protective structure 111. These cavities 112 are semi-hermetically sealed after the method is completed. As such, electronic elements 113 (e.g., devices, circuits and other electronic components) provided over or fabricated from the second substrate 110 are protected by the structure 111. Notably, the cavities 112 may have an inert gas (N) provided therein during the disposing of the structure 111 and the adhesion of the structure 111 to the substrate 110. As is known, before curing, the polymer materials used for the structure 111 may not have the structural rigidity to maintain the cavities 112. Thus, the cavities 112 may collapse. Use of an inert gas for pressure provides the needed strength to maintain the integrity of the cavities until the polymers are cured.

FIG. 1F shows the protective structure 111 disposed over the second substrate 110, with the first substrate 101 having been removed. The removal of the first substrate 101 is effected mechanically in the present representative embodiment. For example, the first substrate 101 may be removed using a vacuum chuck, wedging device such as a knife blade or similar device. The force required to remove the first substrate 101 from the structure 111 depends on the materials selected. Notably, however, because the materials used for the adhesion layers 102, 103 and the structure 111 are selected to be rather easily separated, in no case is the force required to separate the first substrate 101 from the second substrate 110 great enough to compromise the integrity of the structure 111, or the adhesion of the structure 111 to the second substrate 110, or the seal provided. For example, use of BCB for the cap 105 results in a comparatively low-force mechanical separation of the cap layer 105 from the second adhesive layer 103 (e.g., gold) on the first substrate 101. The use of polyimide for the cap layer 105 may provide a greater adhesion to the gold, but the first substrate 101 can be removed using a vacuum chuck, wedging device such as a knife blade or other similar device and without disturbing the integrity of the structure 111 or its seal to the second substrate 110.

FIG. 1G is a cross-sectional view of the structure 111 disposed over the second substrate 110. The structure 111 includes an optional conduit 114 that extends through to the cavity 112 as shown. Notably, there may be a similar conduit (not shown) disposed over the adjacent cavity 112 if the bridge creates a barrier between the cavities. The conduit 114 may be formed by exposure and developing of the cap 105 in a previous step. For example, the conduit 114 may be formed during the process sequence described in connection with FIG. 1B. Alternatively, if the cap 105 were not made of a photo-definable material, the conduit 114 may be formed by a known etching method.

The conduit 114 usefully provides an outlet for gasses formed during the heating sequences applied during curing. To this end, and as will be appreciated by one of ordinary skill in the art, the curing of the polymer materials used for the structure 111 may result in the release of chemicals that can have a deleterious impact at least on electrical elements 113. For example, the solute present in many photo-definable polymers at curing or gasses created during curing may be released during cure. As such, it is useful to remove these gases. The conduit 114 usefully provides an outlet for these gasses. After the outgassing has been completed a material is provided in the conduit to maintain semi-hermeticity of the cavities 112.

The material provided in the conduit 114 may be a small amount of polymer that may be cured later. Alternatively, other materials suitable for this function are contemplated. In representative embodiments, a layer of the material is provided over the top surface of the structure 111 and into the conduit. After exposing and developing, the material at least partially fills the conduit. The material is then cured by a heating/baking step.

FIG. 1H shows a third substrate 115 disposed over the cap 105. The third substrate 115 is disposed over the cap layer 105 after the removal of the second substrate 101. The third substrate 115 is similar or identical in composition to the first substrate 101 and also functions as a transfer substrate. An adhesive layer 116 adheres the third substrate 115 to the cap layer 105. In an illustrative embodiment, the layer 116 is a thermal-release adhesive or UV-release adhesive, well-known to one of ordinary skill in the art. Notably, the adhesive layer 116 provides a sufficient bond of the third substrate 115 to the cap layer 105 to ensure structural integrity of the protective structure 111 and its connection to the second substrate during subsequent processing.

After adhesion of the third substrate 115 to the cap layer 105, the second substrate 110 may be thinned to a thickness chosen for the application of the circuit on the substrate 110. For example, in many high frequency applications (e.g., RF, microwave and millimeter wave applications), substrates are thinned to provide desired electrical characteristics and to improve heat dissipation. In high-frequency and other applications, making electrical connections (e.g., vias) is also facilitated by having thinner substrates. Thus, thinning the substrate to thicknesses of 50 μm or less may be beneficial if not required. Furthermore, after a coarse thinning (e.g., grinding), polishing the substrate may be desired to remove grind damage and make subsequent processing easier.

The noted thinning and polishing steps can tax the integrity of the protective structure 111 and its bond to the second substrate 110. Beneficially, the third substrate 115 provides structural strength and provides a surface for holding the structure during thinning. Moreover, the substrate 115 provides another protective structure against chemicals used during polishing.

FIG. 1I shows the third substrate 115 and the protective structure 111 disposed over a thinned device substrate 117. The substrate 117 may be thinned first by a coarse step, such as attained with a diamond grinder or similar device. The substrate may then be polished to a desired surface smoothness using a known polishing method such as mechanical polishing. Beneficially, during the grinding and polishing steps the third substrate 115 provides protection to the structure 111 and its adhesion to the substrate 117.

After completing the substrate thinning step, electrical connections such as conductive vias (not shown) may be formed in the substrate 117. The conductive vias may be formed as described in other embodiments herein. Furthermore, the substrate 117 may be singulated after the electrical connections are formed. As will be appreciated, the dicing or singulation of the substrate is carried out to provide a plurality of components each packaged with a respective protective structure 111. Singulation may be carried out by known methods. One known method for singulation is described in U.S. Pat. No. 6,777,267, entitled “Die Singulation Using Deep Silicon Etching”, to Richard C. Ruby, et al. The disclosure of this patent is specifically incorporated herein by reference.

After the connections are made, the third substrate 115 is removed. The removal may involve heating the layer 116 or exposing the layer 116 to UV light, depending on the type of material selected.

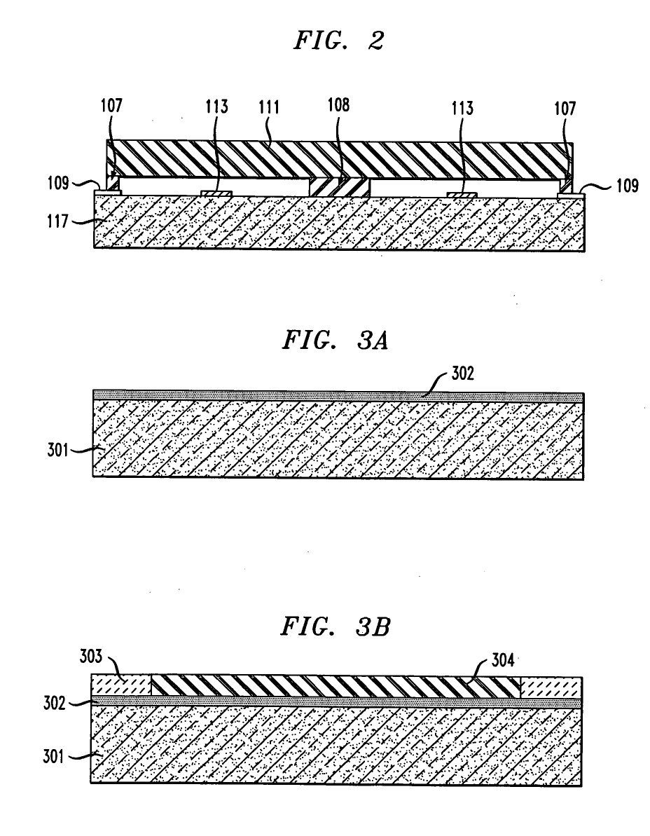

FIG. 2 is a cross-sectional view of a packaged component comprising the thinned device substrate 117 and having the protective structure 111 disposed thereover. In addition to providing mechanical protection to the elements 113, the protective structure 111 provides a seal that ensures that contaminants are prevented from deleteriously impacting the elements 113 and their characteristics.

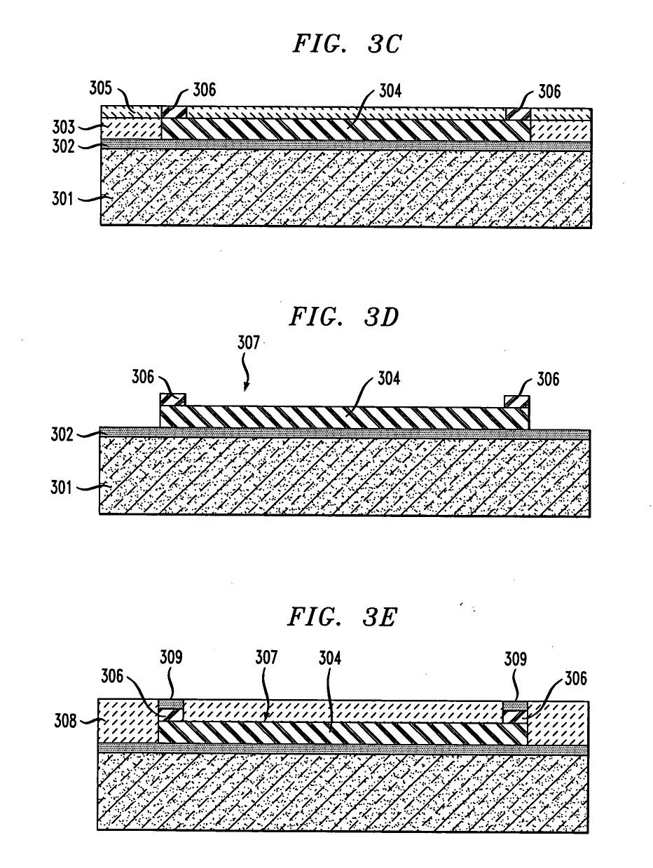

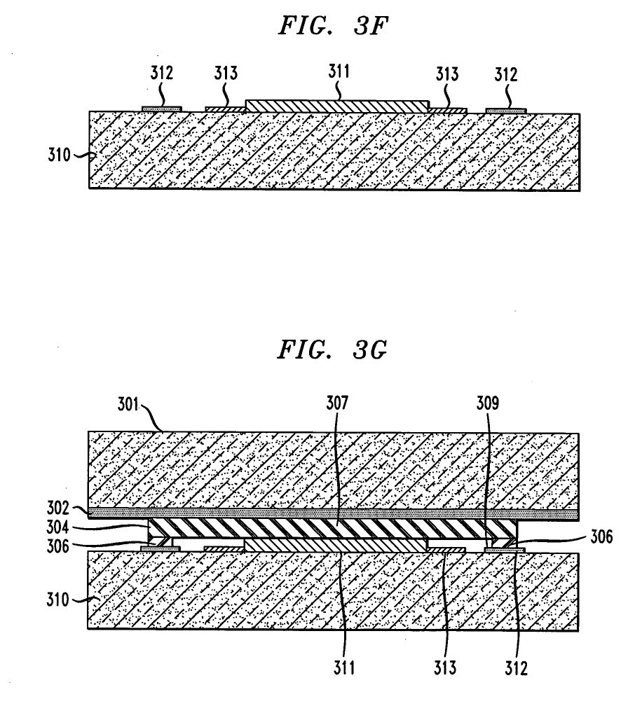

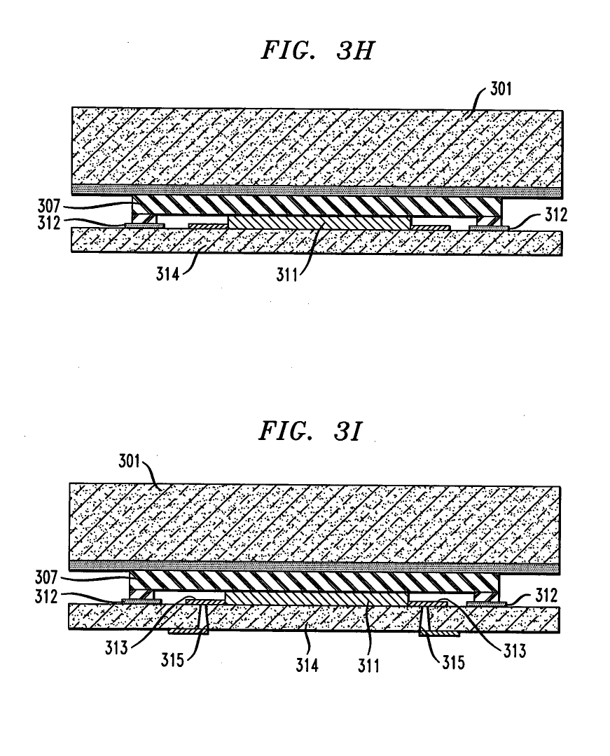

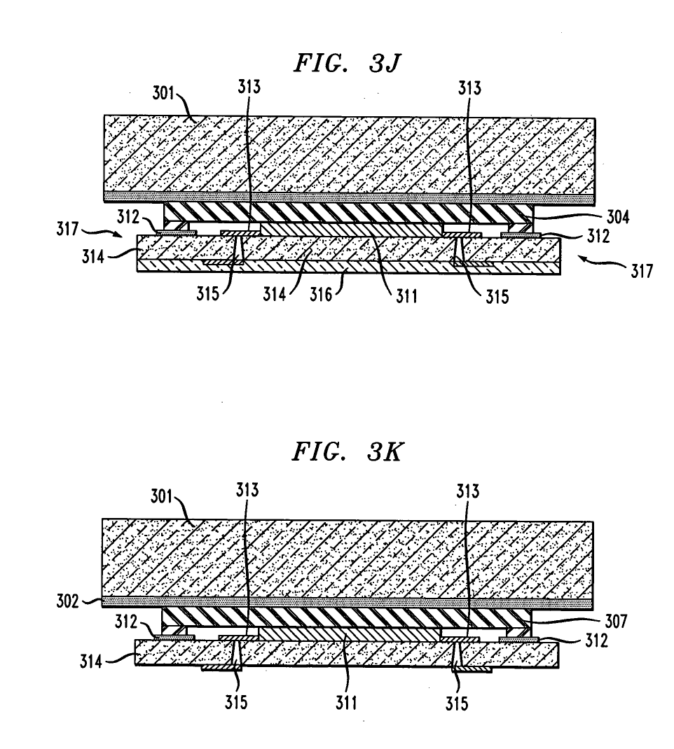

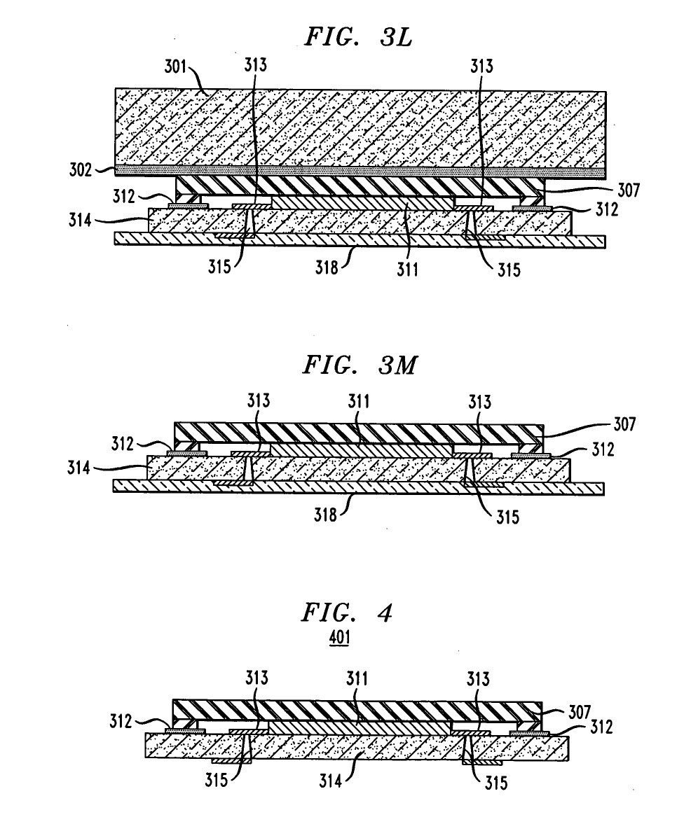

FIGS. 3A-3M are cross-sectional views showing a process sequence of a method in accordance with illustrative embodiments. The method described presently shares many common materials, processing steps and methods as described in connection with the embodiments of FIGS. 1A-2. Details of the common materials, processing steps and methods are generally not repeated to avoid obscuring the description of the present embodiments.

FIG. 3A shows a first substrate 301 (transfer substrate) with a layer 302 disposed thereover. The first substrate 301 may be similar to or the same as the first substrate described in connection with FIGS. 1A-2. The layer 302 is selected for superior adhesion properties to the first substrate 301, the benefits of which will become clearer as the present description continues. In general, the layer 302 is selected to chemically bond to the first substrate 301. In a specific embodiment, the layer 302 is phosophorous silicate glass (PSG), which is deposited to a thickness of approximately 4.0 μm by low pressure chemical vapor deposition (LPCVD) or similar method. This is merely illustrative, and other materials are contemplated, depending on the material of the substrate and other considerations.

FIG. 3B shows a layer 303 disposed over the layer 302. The layer 303 is illustratively a photo-definable material such as those described in connection with previously described embodiments. FIG. 3B shows the layer 303 having been exposed under mask to form a cap layer 304.

FIG. 3C shows a layer 305 disposed over the layer 303 and the cap layer 304. Layer 305 may be of the same material as layer 303, or as noted previously, may be a different material selected for properties such as adhesion to a device substrate. FIG. 3C shows the layer 305 having been exposed under mask to form a gasket 306. Although not shown, a bridge such as described previously may be formed when the gasket 306 is formed.

FIG. 3D shows the cap layer 304 and gasket 306 after developing of the photo-definable materials of layers 303, 305, resulting in a protective structure 307. The protective structure 307 is cured in a slow-bake sequence known to those of ordinary skill in the art. Notably, in an alternative embodiment, the cap layer 304 is cured before forming the gasket 306. In such an embodiment, the forming of an adhesive layer described in connection with FIG. 3E may be foregone. The gasket 306 is then cured after contacting the gasket 306 to the second (device) substrate, thereby providing the bonding of the protective structure 307 to the second substrate.

FIG. 3E shows the forming of an adhesive layer 309 from a layer 308 of photodefinable material. The layer 308 is exposed under mask to form the adhesive layer 309 over the gasket 306. The layer 309 is developed resulting in the protective structure 307 having an adhesive layer 309 disposed over the gasket 306. The adhesive layer 309 is used to ensure adhesion of the structure to the device substrate.

As noted above, many photodefinable materials that are attractive for use in the structure 307 provide rather poor adhesion to device substrates. However, the curing of the photodefinable materials may have a deleterious impact on the electronic elements formed from or disposed over the device substrate. According to the representative embodiment, by curing the structure 307 before disposing over the device substrate outgassing problems associated with curing are substantially avoided. Beneficially though, the bonding strength of the structure 307 to the device substrate is not compromised, because the adhesive layer 309 is not cured until after being disposed over the device substrate. Moreover, because the volume of material used for adhesive layer 309 is comparatively small, outgassing affects during curing of the adhesive layer have minimal impact.

FIG. 3F shows a second substrate (device substrate) 310 having an electronic component 311, an optional layer 312 of adhesive material and electrical contacts 313. The substrate 310 may be one of a variety of substrate materials noted previously. The optional layer 312 may be one of the photodefinable materials noted previously, or may be another adhesive material within the purview of one of ordinary skill in the art. The layer 312 is selectively disposed over the second substrate 310 so as to substantially align with the gasket 306 of the structure 307. If a photo-definable material is used, the layer 312 is formed by providing a layer (not shown) of photo-definable material and exposing and developing the layer by methods described previously. Finally, the contacts 313 are formed of a suitable electrically conductive material (e.g., Au) and by known techniques.

FIG. 3G shows the first substrate 301 disposed over the second substrate 310, with the protective structure 307 therebetween. The substrates 301, 310 are aligned so the adhesive layer 309 contacts the layer 312 as shown. After the substrates 301, 310 are aligned and contact is made, a heating and bonding force step is undertaken allowing layers 309, 312, as applicable, to bond and cure.

The structure shown in FIG. 3G provides needed mechanical strength and hermeticity to allow subsequent processing, such as during a thinning step of the device substrate 310. FIG. 3H shows a thinned and, optionally polished device substrate 314. The thinning and polishing of the substrate 314 may be effected by methods described previously.

FIG. 3I shows the forming of electrical connections 315. In a representative embodiment, after the substrate 314 is thinned and optionally polished, the electrical connections 315 are made through the substrate 314 and to contacts 313. The connections 315 may be plated/filled vias that are etched into the substrate 314 using one of a variety of known methods. For example, the vias may be etched using a reactive ion etching technique, such as deep reactive ion etching (DRIE). Alternatively, the vias may be formed in a known wet-etching sequence. Metal or other suitable electrically conductive material is then provided in the vias by known methods to form the connections 315. Notably, the first substrate 301, being bonded to the substrate 314, as well as the protective structure 307 provide requisite protection of vulnerable components during the etching and conductor/metal forming sequence.

As noted previously, the dicing or singulation of the wafer (substrate 314) needs to be carried out to provide a plurality of components each packaged with a respective structure 307. Various methods of singulation are contemplated. For example, singulation according to the method described in U.S. Pat. No. 6,777,267, referenced previously, may be used. Alternatively, singulation by wet-etching may be carried out. An etching method to carry out singulation and removal of the first substrate 301 according to an illustrative embodiment is described presently.

FIG. 3J shows a layer of photoresist 316 disposed over a lower surface of the substrate 317 and along a scribe line (not shown). An etch step is carried out through to the cap layer 304, with the regions 317 having been removed along the scribe line. In a representative embodiment, the singulation etch is an RIE etching step, such as DRIE using the known Bosch-method or other known deep etch processes. The singulation etch may be carried out in accordance with the method disclosed in the referenced patent to Ruby, et al.

As shown in FIG. 3K, the photoresist 316 is removed by known method such as plasma ashing known to one of ordinary skill in the art. Usefully, plasma ashing can remove (clean) any residual polymer in the trench scribe line area at the surface of layer 302, which is illustratively PSG.

As shown in FIG. 3L, a layer of adhesive 318 is disposed along the lower surface of the (singulated) substrate 314. This layer 318 may be an adhesive tape commonly used in semiconductor processing, such as described in the referenced application to Ruby, et al. Beneficially, the layer 318 is used in order to maintain the singulated pieces in place during further processing steps.

FIG. 3M shows the removal of the first substrate 301 and the layer 302. In the present embodiment, the first substrate 301 is removed by immersing the taped singulated substrate 314 in a solution that will dissolve layer 302, but will not harm the first substrate 301, or the second substrate 314, or the protective structure 307, or the bond/seal between the protective structure 307 and the substrate 314, or the adhesive tape 318, or the bond formed between the adhesive tape 318 and the singulated substrate 314. The solution travels through the scribe lines and etches the layer 302 thus releasing the first substrate 301 from the protective structure 307. In a representative embodiment, the layer 302 is PSG and the solute is dilute buffered hydrofluoric acid (HF). To further aid with the removal of the PSG layer 302 the adhesive tape 318 may be perforated to allow Buffer HF to more directly flow to the PSG 302 throughout the substrate. After removing the first substrate 301 is complete, the taped second substrate 314 is rinsed thoroughly in deionized water.

FIG. 4 shows a packaged structure 401 after removal of the tape 318. The packaged structure 401 comprises the protective structure 307 disposed over the substrate 314 with the electronic element 311 and contacts 313 disposed thereover. As will be appreciated by one of ordinary skill in the art, the protective cap 307 provides a semi-hermetic seal and mechanical protection to the components disposed therein. Notably, a plurality of similar packaged structures 401 are fabricated by the representative method from a single device substrate (wafer) in mass-fabrication.

In connection with illustrative embodiments, a method of fabricating a protective structure and a packaged structure including a protective structure are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A method of forming a protective structure, the method comprising:
disposing a layer of material over a first substrate;
defining features of the protective structure in the layer of material;
bonding the protective structure to a second substrate; and
separating the first substrate from the second substrate.

2. A method as claimed in claim 1, wherein the layer of material is a photo-definable material, and the defining the features further comprises: exposing the layer of material to light and developing the material.

3. A method as claimed in claim 2, wherein the layer of photo-definable material is a polymer material.

4. A method as claimed in claim 2, wherein the features comprise a gasket that contacts the second substrate.

5. A method as claimed in claim 1, further comprising, before the disposing, providing an adhesive between the first substrate and the layer of material.

6. A method as claimed in claim 1, further comprising, singulating the second substrate to provide a plurality of packaged structures, each having a protective cap disposed thereover.

7. A method as claimed in claim 6, wherein the singulating further comprises: providing scribe lines in the second substrate; and etching the second substrate.

8. A method as claimed in claim 7, wherein the separating and the etching are a single step.

9. A method as claimed in claim 4, wherein the protective structure further comprises a cap layer, and the defining the features further comprises:
forming the cap layer;
forming the gasket; and
curing the cap layer and the gasket.

10. A method as claimed in claim 1, wherein the method further comprises, after the separating the first substrate from the second substrate: curing the protective structure; and providing a third substrate over the protective structure.

11. A method as claimed in claim 10, further comprising, after the providing the third substrate, thinning the second substrate.

12. A method as claimed in claim 10, providing an UV-release adhesive material or a thermal-release adhesive material between the protective structure and the third substrate.

13. A method as claimed in claim 4, wherein the bonding further comprises, contacting the gasket to the second substrate, and curing the gasket.

14. A method as claimed in claim 10, further comprising providing an opening in the cap layer, wherein the opening is adapted to release gases from the curing.

15. A method as claimed in claim 9, further comprising:
after the curing, providing an adhesive material over the gasket.

16. A method as claimed in claim 15, wherein the providing the adhesive material further comprises:
providing another layer of photo-definable material over the cap and the gasket; and
exposing the other layer of photo-definable material.

17. A packaged structure, comprising:
a protective structure, which includes a cap layer and a gasket comprised of a photo-definable material.

18. A packaged structure as claimed in claim 17, further comprising a substrate having an electronic element, wherein the protective structure is disposed over the substrate and the electronic element.

19. A packaged structure as claimed in claim 17, wherein the photo-definable material and the layer are a polymer material.

20. A packaged structure as claimed in claim 17 wherein the substrate one of: a Group III-V semiconductor material, silicon, SiGe, or ceramic.
